(19) United States
(12) Patent Application Publication
(10) Pub. No.: US 2006/0145248 A1
(43) Pub. Date: Jul. 6, 2006

(54) LDMOS transistor

(75) Inventor: Suk Kyun Lee, Bucheon-city (KR)

Correspondence Address: MCKENNA LONG & ALDRIDGE LLP, 1900 K STREET, NW, WASHINGTON, DC, 20006, US

(73) Assignee: DongbuAnam Semiconductor Inc., Kangnam-Ku (KR)

(21) Appl. No.: 11/319,478

(22) Filed: Dec. 29, 2005

(30) Foreign Application Priority Data
Dec. 30, 2004 (KR) 10-2004-0117143

(51) Int. Cl. H01L 29/76

(52) U.S. Cl. 257/335

(57) ABSTRACT

A lateral double-diffused MOS (LDMOS) transistor is provided with a trench source structure. The LDMOS transistor includes a semiconductor substrate of a first conductivity, the semiconductor substrate having a trench formed in a surface region corresponding to a source of the transistor; a body of a second conductivity, the body disposed in the semiconductor substrate to surround the trench; and a source region of the first conductivity, the source region forming a sidewall of the trench.

### CROSS REFERENCE TO RELATED APPLICATION

This application claims the benefit of Korean Patent Application No. 10-2004-0117143, filed on Dec. 30, 2004, which is hereby incorporated by reference for all purposes as if fully set forth herein.

### BACKGROUND OF THE INVENTION

1. Field of the Invention

The present invention relates to a semiconductor device, and more particularly, to a lateral double-diffused metal-oxide-semiconductor (LDMOS) transistor having a trench source structure.

2. Discussion of the Related Art

Referring to FIG. 1, illustrating a typical LDMOS transistor, an n semiconductor substrate 100 has an active region defined by a device isolation layer 110. A p-type body 120 and an n⁻ extended drain region 130 are formed in the n⁻ semiconductor substrate 100 to be separated from each other by a predetermined distance. An n⁺ source region 140 is disposed on the p-type body 120. A channel 121, occurring in the p-type body 120 adjacent the n⁺ source region 140, is overlapped by a gate isolating layer 160 and a gate conducting layer 170, which are sequentially formed atop the channel. Spacers are formed on the sidewalls of the gate conducting layer 170. An n⁺ drain area 150 is disposed on the n⁻ extended drain region 130. The structure is completed by a double diffusion process in which an ion implantation process is carried out twice, i.e., once before formation of the gate spacer layer 180 and again after its formation. The source and drain regions 140 and 150 are electrically connected with a source electrode S and a drain electrode D, respectively.

Due to a resistance of the p-type body 120, however, a parasitic transistor is activated. To prevent such an occurrence, an impurity concentration of the p-type body 120 can be increased, to decrease its resistance and thereby limit the size of the corresponding voltage drop, but increasing the impurity concentration undesirably increases the threshold voltage of the device.

### SUMMARY OF THE INVENTION

Accordingly, the present invention is directed to an LDMOS transistor that substantially obviates one or more problems due to limitations and disadvantages of the related art.

An advantage of the present invention is that it provides an LDMOS transistor having a trench source structure that can reduce the resistance of a p-type body without increasing threshold voltage.

Additional advantages and features of the invention will be set forth in part in the description which follows, and will become apparent from the description, or may be learned by practice of the invention. These and other advantages of the invention may be realized and attained by the structure particularly pointed out in the written description and claims hereof as well as the appended drawings.

To achieve these and other advantages in accordance with the purpose of the invention, as embodied and broadly described herein, there is provided a lateral DMOS transistor having a trench structure, comprising a semiconductor substrate of a first conductivity, the semiconductor substrate having a trench formed in a surface corresponding to a source of the transistor; a body of a second conductivity, the body disposed in the semiconductor substrate to surround the trench; and a source region of the first conductivity, the source region forming a sidewall of the trench.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principles of the invention. In the drawings:

FIG. 1 is a sectional view of a typical LDMOS transistor; and

FIG. 2 is a sectional view of an LDMOS transistor according to an exemplary embodiment of the present invention.

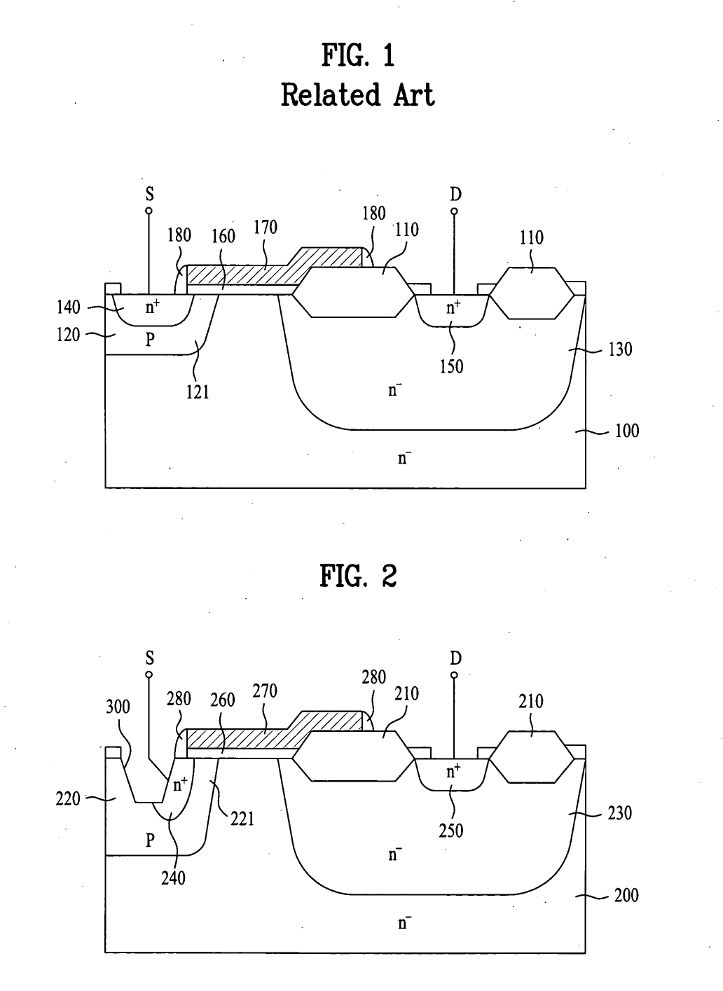

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

The LDMOS transistor according to an exemplary embodiment of the present invention is provided with a trench-structured source. The structure reduces an interface distance along a PN junction, formed between an n-type source and a p-type body, and reduces a voltage drip by reducing the resistance of the p-type body according to the shorten interface distance.

Referring to FIG. 2, illustrating an LDMOS transistor according to an exemplary embodiment of the present invention, an n⁻ semiconductor substrate 200 has an active region defined by a device isolation layer 210. A p-type body 220 and an n⁻ extended drain region 230 are formed in the n⁻ semiconductor substrate 200 to be separated from each other by a predetermined distance. The n⁻ semiconductor substrate 200 includes a trench 300 disposed so that the p-type body 220 surrounds the trench. This structure causes the junction depth of the p-type body to be increased by as much as the depth of the trench, when compared to a typical LDMOS device. Also, the trench 300 is disposed so that an n⁺ source region 240 forms a side surface of the trench. Thus, the majority of the n⁺ source region 240 is disposed in the p-type body 220 to be adjacent a sidewall of the trench 300, and in an exemplary embodiment of the present invention, a lower portion of the n⁺ source region may extend partially under a lower surface of the trench. This structure results in a shortening of the junction between the n⁺ source region 240 and the p-type body 220. The length of the contacting interface is shortened due to the presence and depth of the trench 300. As a result, the resistance is reduced, and a voltage drop caused by a carrier movement decreases, so that the unwanted activation of a parasitic transistor can be controlled.

A channel 221, occurring in the p-type body 220 adjacent the n⁺ source region 240, is overlapped by a gate isolating layer 260 and a gate conducting layer 270, and a gate stack is formed atop the channel by a sequential forming of the gate isolating layer and gate conducting layer. An n⁺ drain region 250 is disposed on the n⁻ extended drain region 230. The structure is completed by a double diffusion process in which a first ion implantation process is carried out before the gate spacer layer 280 is formed, and a second ion implantation process is carried out after the gate spacer layer 280 is formed. The n⁺ source region 240 and the n⁺ drain region 250 are electrically connected with a source electrode S and a drain electrode D, respectively, using general techniques for wiring layer formation. The wiring electrically connects the n⁺ source region 240 and the source electrode S through an insulating material (not shown) filling the trench 300.

Accordingly, in an LDMOS transistor of an exemplary embodiment of the present invention, a trench is formed on a substrate, a body is disposed under the trench, a source region is formed in the body on a sidewall of the trench, so that a junction depth of the body is deepened by as much as the depth of the trench. Therefore, a resistance in the body can be reduced without having to increase an impurity concentration in the body. Consequently, there is no unwanted activation of a parasitic transistor, which can be controlled without having to increase a threshold voltage, thereby improving device stability.

It will be apparent to those skilled in the art that various modifications and variations can be made in the present invention without departing from the spirit or scope of the invention. Thus, it is intended that the present invention covers such modifications and variations provided they come within the scope of the appended claims and their equivalents.

What is claimed is:

1. A lateral double-diffused MOS transistor, comprising:
a semiconductor substrate of a first conductivity, said semiconductor substrate having a trench formed in a surface corresponding to a source of the transistor;
a body of a second conductivity, said body disposed in said semiconductor substrate to surround the trench; and
a source region of the first conductivity, said source region located at a sidewall of the trench.

2. The lateral double-diffused MOS transistor according to claim 1, wherein said source region is formed inside said body.

3. The lateral double-diffused MOS transistor according to claim 1, wherein said body has a junction depth that is deepened by as much as the depth of the trench.

4. The lateral double-diffused MOS transistor according to claim 1, wherein the trench is filled with an insulting material.

5. The lateral double-diffused MOS transistor according to claim 4, further comprising:
a source electrode penetrating the insulating material in the trench and electrically connected with the source region.

6. The lateral double-diffused MOS transistor according to claim 1, further comprising:
a drain electrode which is electrically connected with the drain region.

7. The lateral double-diffused MOS transistor according to claim 1, wherein the first conductivity is n-type and wherein the second conductivity is p-type.

8. The lateral double-diffused MOS transistor according to claim 1, further comprising:
an extended drain region of the first conductivity, said extended drain region being formed in a predetermined area of said semiconductor substrate to be separated from said body;
a drain region of the first conductivity, said drain region disposed on said extended drain region; and
a gate stack disposed on a channel occurring in said body.

9. The lateral double-diffused MOS transistor according to claim 8, wherein the first conductivity is n-type and wherein the second conductivity is p-type.

10. A lateral double-diffused MOS transistor, comprising:
a first conductive type semiconductor substrate having a trench;
a second conductive type body surrounding the trench on a predetermined area of the semiconductor substrate;
a first conductive source region disposed adjacent a sidewall of the trench in the body;
a first conductive type extended drain region formed in a predetermined area of the semiconductor substrate to be separated from the body;
a first conductive type drain region disposed on the extended drain region; and
a gate stack disposed on a channel forming area in the body.
